(19) United States
(12) Patent Application Publication
(10) Pub. No.: US 2008/0042269 A1
(43) Pub. Date: Feb. 21, 2008

(54) BUMP STRUCTURES AND PACKAGED STRUCTURES THEREOF

(75) Inventors: Pao-Kang Niu, Hsinchu City (TW); Chien-Jung Wang, Hsin-Chu City (TW); Chang-Chun Lee, Longtan Township (TW)

Correspondence Address: DUANE MORRIS LLP;IP DEPARTMENT (TSMC), 30 SOUTH 17TH STREET, PHILADELPHIA, PA, 19103-4196, US

(73) Assignee: TAIWAN SEMICONDUCTOR MANUFACTURING CO., LTD., Hsin-Chu City (TW)

(21) Appl. No.: 11/465,042

(22) Filed: Aug. 16, 2006

(51) Int. Cl. H01L 23/48

(52) U.S. Cl. 257/737

(57) ABSTRACT

A bump structure for bonding two substrates together includes a composite structure. The composite structure is formed over a first substrate. The composite structure includes at least one first polymer layer and at least one first metal-containing layer. The bump structure also includes a second metal-containing layer at least partially covering a top surface of the composite structure and extending from the top surface of the composite structure to a surface of the first substrate, wherein the second metal-containing layer is thinner than the first metal-containing layer.

### BACKGROUND OF THE INVENTION

1. Field of the Invention

The present invention relates to semiconductor structures, and more particularly to bump structures and packaged structures thereof.

2. Description of the Related Art

With advances associated with electronic products, semiconductor technology has been widely applied in manufacturing memories, central processing units (CPUs), liquid crystal displays (LCDs), light emission diodes (LEDs), laser diodes and other devices or chip sets. In order to achieve high-integration and high-speed goals, dimensions of semiconductor integrated circuits have been reduced. Various materials and techniques have been proposed to achieve these integration and speed goals and to overcome obstacles during manufacturing. Advances have also been made in semiconductor packages. For example, bump structures have been used for enhancing electrical connection between chips and substrates, e.g., printed circuit boards.

FIG. 1 is a schematic cross-sectional view illustrating prior art bump structures. Spherical bump structures 110 are formed on respective metal pad 105 formed over/in a substrate 100. The metal pads 105 are coupled to circuits and devices thereunder so that a current or voltage can be applied to the circuits and devices via the pad structures 105. The bump structures 110 are made of lead/tin (Pb/Sn) alloy. The bump structures 110 provide a conducting path through which an external power source can provide a current or voltage into the circuits and devices thereunder.

After the formation of the bump structures 110, the substrate 100 (with the bump structures 110 formed thereover) is attached to another substrate (not shown), such as a printed circuit board or semiconductor substrate. An underfill (not shown) is formed between the substrates, contacting the bump structures 110. The substrate 100, the bump structures 110, the underfill and the other substrate (not shown) constitute a packaged structure. The underfill is provided for relieving stresses applied on the bump structures 110. The packaged structure is then subjected to various reliability tests, such as thermal and stress tests. In some situations, the bump structure 110 may be cracked by stresses applied to the bump structure 110, when the stresses cannot be properly relieved. Still worse, in some situations a low-k dielectric layer (not shown) formed under the bump structure 110 may crack and peel. In addition, the bump structure 110 is formed on the pad structure 105. In order to achieve a desired electrical connection between the substrates, the spherical bump structure 110 must be sufficiently large, e.g., a minimum diameter of about 150 μm to about 200 μm, and the pad structure 105 must also be large enough, e.g., have a minimum length×width of about 100 μm×100 μm to support the bump structure 110. Because of these large dimensions, size reduction of the chip becomes difficult, even when a small-dimension technology is used for manufacturing the chip.

By way of background, U.S. Pat. No. 5,578,527 provides a description of a connection construction, the entirety of which is hereby incorporated by reference herein. In the reference, conductive particles contact composite bumps that are comprised of a polymer body having a relatively low Young's Modulus and a conductive metal coating to form the connection structure. The relatively low Young's Modulus of the composite bumps reduces recoil forces during bonding. However, the composite bump is formed on the pad. As described above, such a structure will still face difficulties in reducing chip dimensions.

From the foregoing, improved bump structures and packaged structures thereof are desired.

### SUMMARY OF THE INVENTION

In accordance with some exemplary embodiments, a bump structure for bonding two substrates together includes a composite structure. The composite structure is formed over a first substrate. The composite structure includes at least one first polymer layer and at least one first metal-containing layer. The bump structure also includes a second metal-containing layer at least partially covering a top surface of the composite structure and extending from the top surface of the composite structure to a surface of the first substrate, wherein the second metal-containing layer is thinner than the first metal-containing layer.

In accordance with some exemplary embodiments, a packaged structure comprises a plurality of bump structures formed over a first substrate and a plurality of first pad structures formed over a second substrate. Each of the bump structures comprises a first polymer layer, a first metal-containing layer and a second metal-containing layer. The first polymer layer is formed over a first substrate. The first metal-containing layer is formed over the first polymer layer. The second metal-containing layer at least partially covers a top surface of the first metal-containing layer, and extends from the top surface of the first metal-containing layer to a surface of the first substrate, wherein the second metal-containing layer is thinner than the first metal-containing layer. At least some of the bump structures are attached to corresponding first pad structures from the second substrate.

The above and other features of the present invention will be better understood from the following detailed description of the preferred embodiments of the invention that is provided in connection with the accompanying drawings.

### BRIEF DESCRIPTION OF THE DRAWINGS

Following are brief descriptions of exemplary drawings. They are mere exemplary embodiments and the scope of the present invention should not be limited thereto.

FIG. 1 is a schematic cross-sectional view illustrating bump structures.

FIGS. 2A-2F are schematic cross-sectional views of embodiments of exemplary bump structures formed over pad structures.

FIG. 3 is a schematic top view of an exemplary regional layout comprising a pad region and bump structures, wherein the bump structures are not formed on the pad structures.

FIGS. 4A-4F are schematic cross-sectional views showing a process for formation of an exemplary bump as shown in FIG. 3 taken along section line 4F-4F of FIG. 3.

FIG. 5 is a schematic cross-sectional view showing an exemplary packaged structure comprising the bump structure shown in FIG. 2A.

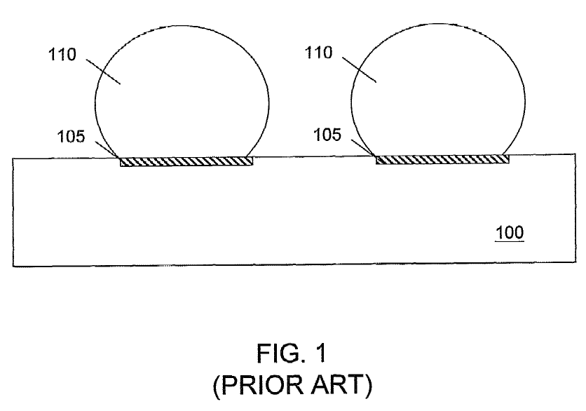

### DESCRIPTION OF THE PREFERRED EMBODIMENT

This description of the exemplary embodiments is intended to be read in connection with the accompanying drawings, which are to be considered part of the entire written description. In the description, relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation.

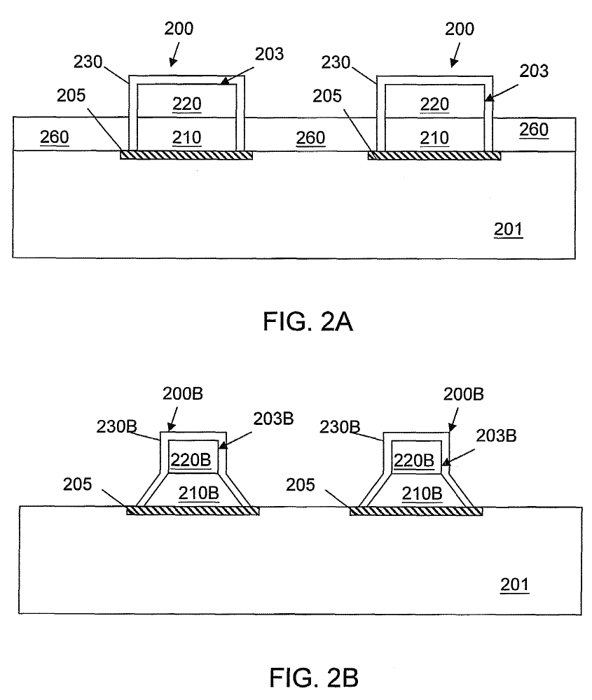

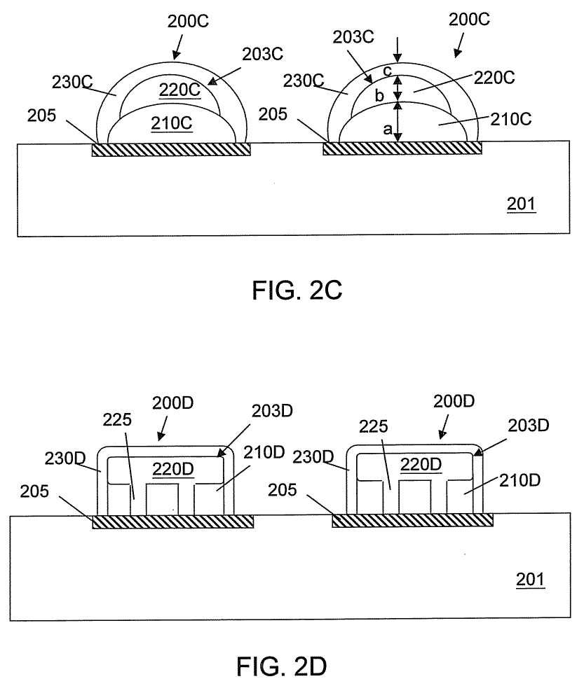

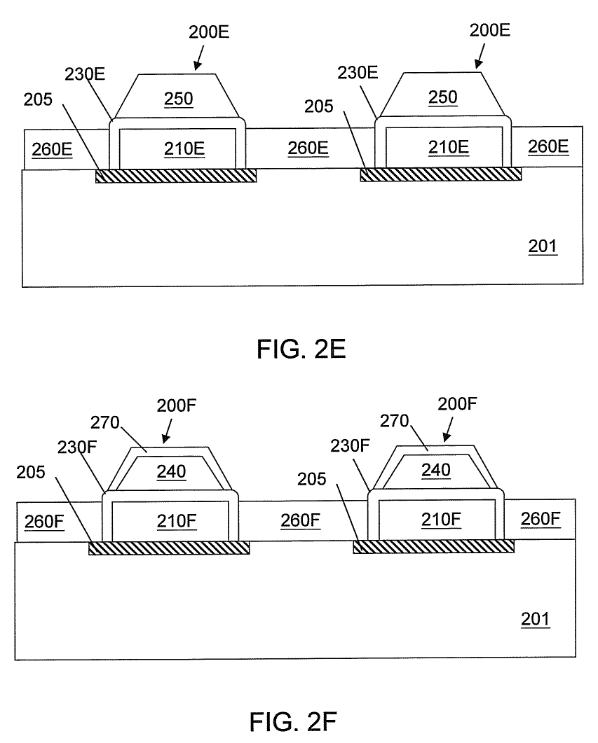

FIGS. 2A-2F are schematic cross-sectional views of embodiments of exemplary bump structures formed over pad structures.

Referring to FIG. 2A, a substrate 201 comprises at least one pad structure, e.g., pad structures 205, formed therein or thereover. Bump structures 200 are formed over the pads 205. In some embodiments, a bump structure 200 comprises a composite structure 203 and a metal containing layer 230. The composite structure 203 comprises at least one polymer layer 210 and at least one metal-containing layer 220. The composite structure 203 is formed over the pad structure 205 of the substrate 201. The metal-containing layer 230 at least partially covers a top surface of the metal-containing layer 220 and extends from the top surface of the composite structure 203 along the side surfaces of the metal-containing layer 220 and the polymer layer 210 to a surface of the substrate 201, such as the pad structure 205. In some embodiments, the metal-containing layer 220 is formed over the polymer layer 210 as shown in FIG. 2A. In other embodiments, the polymer layer 210 is formed over the metal-containing layer 220.

The substrate 201 can be a silicon substrate, III-V compound substrate, display substrate such as a liquid crystal display (LCD), plasma display, cathode ray tube display or electro luminescence (EL) lamp display, or light emitting diode (LED) substrate (collectively referred to as, substrate 201), for example. The pad structure comprises, for example, a metal-containing layer (such as aluminum (Al), copper (Cu) or Al/Cu), polyislicon layer or other layer of conductive material.

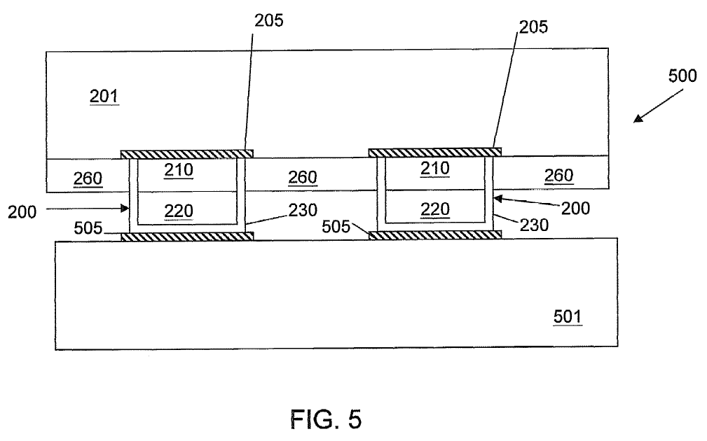

The polymer layer 210 can be a layer of thermoplastic, thermoset, elastomer, or coordination polymer. The polymer layer 210 is formed as a stress buffer layer for releasing normal and shear stresses applied to the bump structure 200, such as when the bump structure 200 is attached to a pad structure of another substrate (not shown in FIG. 2A, but shown in FIG. 5) and subjected to a stress test. In some embodiments, the polymer layer 210 has a thickness between about 50 μm to about 60 μm from the top surface of the pad structure 205 to the top surface of the polymer layer 210. The thickness of the polymer layer 210 may be selected based upon the anticipated stresses applied to the bump structure 200. In one embodiment, the thickness of the polymer layer 210 is selected so that the bump structure 200 is not substantially damaged when it is subjected to a stress test. The polymer layer 210 can be formed by a spin-coating process, for example. In some embodiments, the cross-sectional view of the polymer layer 210 can be, for example, square or rectangular.

The metal-containing layer 220 can be, for example, a lead-free alloy (such as gold (Au) or a tin/silver/copper (Sn/Ag/Cu) alloy), a lead-containing alloy (such as a lead/tin (Pb/Sn) alloy) or other bump metal material. The metal-containing layer 220 is formed as a conducting path as well as a stress buffer layer for releasing a normal stress. In some embodiments, the metal-containing layer 220 has a thickness between about 50 μm to about 60 μm from the top surface of the polymer layer 210 to the top surface of the metal-containing layer 220. The thickness of the metal-containing layer 220 can vary with the desired electrical connection between the pad structure 205 and a pad structure of another substrate (not shown in FIG. 2A, but shown in FIG. 5). The metal-containing layer 220 can be formed by, for example, a physical vapor deposition (PVD) process, chemical vapor deposition (CVD) process, electro-chemical plating process, electroless chemical plating process or other method that is adapted to form a metal-containing layer.

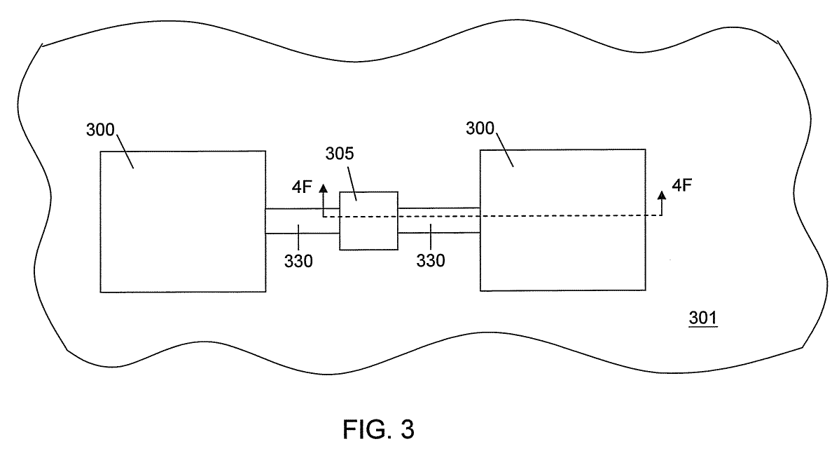

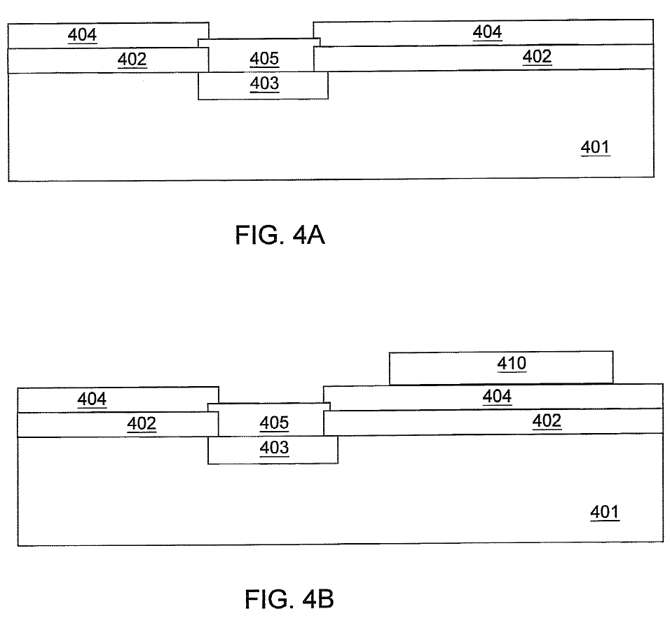

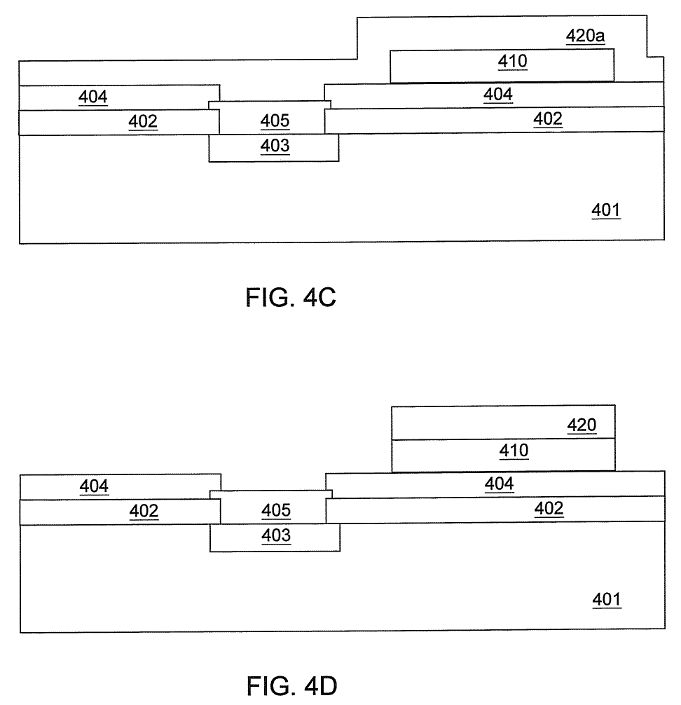

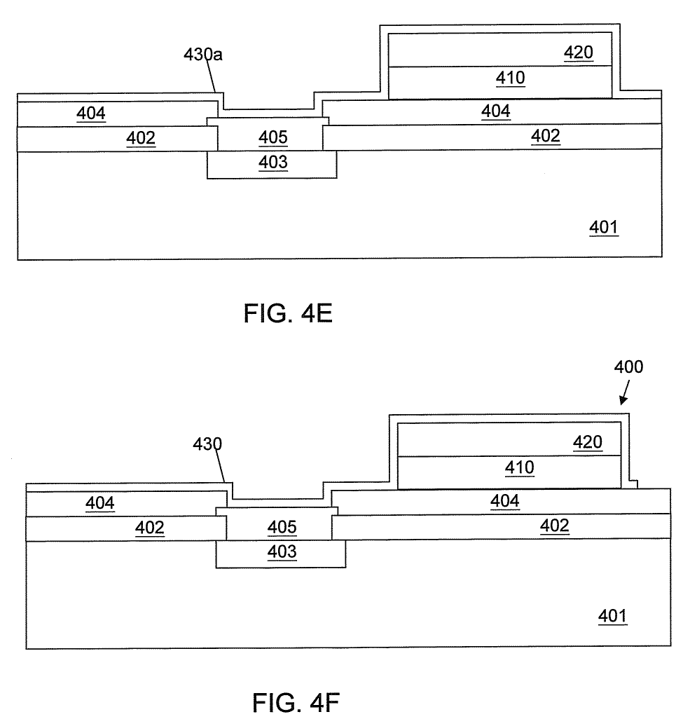

The metal-containing layer 230 can be, for example, Al, Cu, Al/Cu or other layer of conductive material. The metal-containing layer 230 also provides a desired stress-relief functionality. When the bump structure 200 is attached to a pad structure of another substrate (not shown in FIG. 2A, but shown in FIG. 5) and subjected to a stress test, the metal-containing layer 230 can effectively release stresses applied to the bump structure 200. Further, the metal-containing layer 230 provides other features as described in connection with the descriptions of FIGS. 3 and 4A-4F. In some embodiments, the metal-containing layer 230 can be formed by, for example, a PVD process, CVD process, electrochemical plating process, electroless chemical plating process or other method that is adapted to form a metal-containing layer.

In some embodiments, the metal-containing layer 230 has a thickness of about 5,000 Å or less from the top surface of the metal-containing layer 220 to the top surface of the metal-containing layer 230. The thickness of the metal-containing layer 230 can vary according to the desired amount of stress-relief and particular electrical connection needed between the pad structure 205 and a corresponding pad structure of another substrate. In some embodiments, it is preferred that the metal-containing layer 230 has sufficient thickness so that stresses applied to the bump structure 200, e.g., to the metal-containing layer 230, do not substantially damage or crack the top surface of the metal-containing layer 230. The cracking of the top surface of the metal-containing layer 230 may adversely affect the electrical connection between the pad structure 205 and the pad of another substrate (not shown). However, this may not be a concern when the metal-containing layer 220 provides a desired electrical connection so that current can flow via the metal-containing layer 220 to the portion of the metal-containing layer 230 formed on the sidewalls of the metal-containing layer 220 and the polymer layer 210. As described above, in some embodiments, the polymer layer 210 may be formed over the metal-containing layer 220. In these embodiments, if the polymer layer 210 directly contacts the metal-containing layer 230 at its top surface, the cracking of the metal-containing layer 230 may increase the resistance of the bump structure 200.

In some embodiments, the selection of the material of the metal-containing layer 230 is correlated to the material of the pad structure of another substrate (not shown) to which the bump structure 200 is attached. For example, if the material of the pad structure of the other substrate to which the bump structure 200 is attached is AlCu, the use of AlCu as the metal-containing layer 230 may enhance adhesion between the bump structure 200 and the pad of the other substrate.

In some embodiments, the metal-containing layer 230 only partially covers the top surface of the metal-containing layer 220 as long as a desired electrical connection between the substrate 201 and another substrate can be achieved. In some embodiments shown in the figure, the thin-metal-containing layer 230 completely covers the metal-containing layer 220 and the polymer layer 210. In some embodiments, the bump structure 200 is formed on the pad structure 205. In order to obtain a desired electrical connection between the substrate 201 and another substrate, the pad structure 205 has a dimension of about 100 μm×100 μm for a square pad or a diameter of about 100 μm for a round pad, for example.

In some embodiments, the bump structure 200 also comprises a polymer layer 260 formed adjacent to the sidewall of the metal-containing layer 230. The polymer layer 260 is formed to release stresses applied to the bump structure 200 when the bump structure 200 is attached to a pad structure of another substrate and subjected to a stress test. In some embodiments, the polymer layer 260 has a thickness between about 50 μm to about 60 μm. In still other embodiments, the polymer layer 260 may not be used if the polymer layer 210 within the bump structure 200 provides for the desired relief of stress.

FIG. 2B illustrates a cross-sectional view of an exemplary bump structure 200B with a trapezoidal polymer layer 210B. Items shown in FIGS. 2A and 2B which are analogous are identified by same reference numerals only with the suffix “B” used in FIG. 2B. The polymer layer 210B has a trapezoidal cross-section. The trapezoidal polymer layer 210B can be formed by an anisotropic etch process that has a vertical etch rate higher than a lateral etch rate, for example.

FIG. 2C illustrates a cross-sectional view of an exemplary bump structure 200C with a semi-spherical polymer layer 210c. The semi-spherical bump structure 200C shown in FIG. 2C can be formed by, for example, a thermal treatment, such as an alloy process. Thicknesses of the polymer layer 210C, the metal-containing layer 220C and the metal-containing layer 230C are described above in connection with FIG. 2A and are represented by “a,” “b” and “c” shown in FIG. 2C, respectively.

FIG. 2D illustrates a cross-sectional view of another exemplary bump structure 200D with at least one conductive plug 225 formed within a polymer layer. The conductive plugs 225 shown in FIG. 2D can be, for example, via/contact plugs, lines or other shape of material and extend through the polymer layer 210 to the pad structure 205. In some embodiments, the conductive plugs 225 comprise a material similar to that of the metal-containing layer 220D. Further, in some embodiments, the conductive plugs 225 and the metal-containing layer 220D are formed by the same formation process.

FIG. 2E illustrates a cross-sectional view of another exemplary bump structure 200E formed over a pad structure. In this embodiment, the metal-containing layer 220 is not formed between the polymer layer 210E and the metal-containing layer 230E as shown in FIG. 2A. Instead, a conductive layer 250 is formed over the metal-containing layer 230E.

The bump structure 200E comprises polymer layer 210E, metal-containing layer 230E and conductive layer 250. The polymer layer 210E is formed over the substrate 201. The metal-containing layer 230E is formed over the polymer layer 210, wherein the metal-containing layer 230E at least partially covers the polymer layer 210E and extends from the top surface of the polymer layer 210E to a surface of the substrate 201, such as to the pad structure 205. The conductive layer 250 is formed over the metal-containing layer 230E, substantially covering a top surface of the metal-containing layer 230E. In some embodiments, the conductive layer 250 is similar in composition and thickness to the metal-containing layer 220 as shown in FIG. 2A. The conductive layer 250 is formed to achieve a desired electrical connection and stress relief level between the pad structure 205 and a pad of another substrate (not shown in FIG. 2E, but shown in FIG. 5).

As described above, in some embodiments, the selection of the material of the conductive layer 250 may be correlated to the material of a pad structure of another substrate to which the bump structure 200E is to be attached. For example, if the conductive layer 250 is a metal-containing layer, such as a bump metal layer, the bump structure 200E may comprise the same material so as to achieve good adhesion between the pad structure 200 and the pad of the other substrate.

FIG. 2F illustrates a cross-sectional view of another exemplary bump structure formed over a pad structure. A polymer layer 240 is formed between a thin conductive layer 270 and the metal-containing layer 230F, and covered by the conductive layer 270. In some embodiments, the material of the polymer layer 240 can be similar to that of the polymer layer 210F and formed by the same polymer formation process, for example. In some embodiments, the material of the conductive layer 270 is similar to that of the metal-containing layer 230F. The polymer layers 210F and 240 can provide a desired release of normal and shear stresses applied to the bump structure 200F, when the bump structure 200F is subjected to a stress test. In addition, the metal-containing layer 230F and the conductive layer 270 can provide a desired electrical connection between the pad structure 205 and a pad of another substrate.

From the foregoing, the polymer layers are provided as a buffer layer such that stresses coming from a bumping process step can be desirably released.

FIG. 3 is a schematic top view of an exemplary regional layout comprising a pad region and bump structures, wherein the bump structures are not formed on the pad structures, but rather are laterally spaced therefrom. Items from the structure in FIG. 3 which are analogous to items from the structure shown in FIG. 2A are identified by reference numerals that are increased by 100. The regional layout comprises two bump structures 300 and a pad structure 305. The bump structures 300 are connected to the pad structure 305 via the metal-containing layer 330 as described in detail below.

FIGS. 4A-4F are schematic cross-sectional views showing a process for formation of an exemplary bump structure as shown in FIG. 3 taken along section line 4F-4F of FIG. 3. Items from the structure in FIGS. 4A-4F which are analogous to items from the structure in FIG. 2A are identified by reference numerals that are increased by 200.

Referring to FIG. 4A, a metal-containing layer 403 is formed within or over the substrate 401. Passivation layers 402 and 404 are sequentially formed over the substrate 401. A pad structure 405 is formed within an opening formed through the passivation layers 402 and 404 and contacts the metal-containing layer 403. The metal-containing layer 403 is coupled to at least one device or circuit (not shown) formed under the passivation layer 402. The metal-containing layer 403 is generally referred to as the “top metal layer.” The metal-containing layer 403 can be, for example, a layer of Cu, Al, AlCu or other metal-containing material that can be formed by, for example, a PVD process, CVD process, electrochemical plating process, electroless chemical plating process or other method that is adapted to form a conductive layer as will be familiar to those in the art.

The passivation layer 402 comprises a polymer layer or a dielectric layer, for example. In some embodiments, the passivation layer 402 can be a multi-layer structure, such as nitride/oxide/nitride/oxide having thickness of about 750 Å/2,000 Å/4,000 Å/2,000 Å, respectively. The multi-layer structure can be formed, for example, by CVD. The passivation layer 404 comprises a polymer layer or dielectric layer, for example. In some embodiments, the passivation layer 404 can be a multi-layer structure, such as plasma enhanced (PE) oxide/nitride having a thickness of about 4,000 Å/6,000 Å, respectively. The multi-layer structure can be formed, for example, by CVD. The opening (not shown) within the passivation layers 402 and 404 can be formed by the same or different photolithographic processes and etch processes.

FIG. 4B shows a polymer layer 410 formed over the passivation layer 404. As described above, a layer of polymer provided to form the polymer layer 410 can be formed over the passivation layer 404 by a spin-coating process, for example. The layer of polymer is then patterned by an exposure process and a development process to form the polymer layer 410 as shown in FIG. 4B.

FIG. 4C shows a layer of metal-containing material 420a formed over the structure shown in FIG. 4B. The layer of metal-containing material 420a is provided to form the metal-containing layer 420 (shown in FIG. 4D). The layer of metal-containing material 420a can be, for example, a layer of lead-free alloy (such as Au or a Sn/Ag/Cu alloy), lead-containing alloy (such as a Pb/Sn alloy) or other bump metal material which can be formed by a PVD process, CVD process, electrochemical plating process, electroless chemical plating process or other method that is adapted to form a metal-containing layer, for example.

FIG. 4D shows the metal-containing layer 420 is defined and formed over the polymer layer 410. After the formation of the layer of metal-containing material 420a, a photolithographic process and an etch process are used to pattern the layer of metal-containing material 420a to remove a portion of the layer of metal-containing material 420a to form the metal-containing layer 420. In some embodiments, the layer of polymer and the layer of metal-containing material 420a can be patterned by the same photolithographic process and etch process. In still other embodiments, the formation of the polymer layer 410 and the metal-containing layer 420 can be formed by respective photolithographic process and etch process.

FIG. 4E shows a thin layer of metal-containing material 430a formed over the substrate shown in FIG. 4D. In some embodiments, the thin layer of metal-containing layer 430a is formed substantially conformal over the pad structure 405 and the metal-containing layer 420. As described above, the thin layer of the metal-containing material 430a can be, for example, Al, Cu, Al/Cu or other layer of conductive material that is formed by a PVD process, CVD process, electro-chemical plating process, electroless chemical plating process or other method that is adapted to form a thin layer metal-containing material, for example.

FIG. 4F is a schematic cross-sectional view of the structure shown in FIG. 3 taken along section line 4F-4F. After the formation of the thin layer of metal-containing material 430a, a photolithographic process and an etch process are used to remove a portion of the thin layer of metal-containing material 430a to form a desired metal-containing layer 430 as shown in FIG. 4F. As also shown in the figure, the bump structure 400 is separated from the pad structure 405. Further, the metal-containing layer 430 extends from the top surface of the metal-containing layer 420 to the pad structure 405, providing electrical connection between the pad structure 405 and a pad of another substrate (not shown in FIG. 4F, but shown in FIG. 5) through the bump structure 400. Based on the layout design shown in FIG. 3, the bump structure 400 is not formed on or over the pad structure 405. The electrical connection between the substrates is mainly attributed to the metal-containing layer 430. The polymer layer 410 and the metal-containing layer 420 are formed as stress buffers between the substrates. Without the need for the pad structure 405 to support the bump structure 400 to obtain a desired electrical connection, the dimension of the pad structure 405 can thus be reduced to about 50 μm×50 μm for a square pad or a diameter of about 50 μm for a round pad, for example. In such embodiments, the dimension of the bump structure 400 can also be reduced to about 75 μm×75 μm for a square pad or a diameter of about 75 μm for a round pad, for example, because the desired electrical connection can be provided by the metal-containing layer 430, instead of the bulk of the bump structure 400. With the reduced dimensions of the bump structure 400 and the pad structure 405, a denser layout for the pad structures 405, i.e., a smaller spacing between two neighboring pad structures 405, can be formed over the substrate 401, resulting in reduced chip dimensions. In some embodiments, a pitch of a pad structure, e.g., including a width of the pad structure and a space between two pad structures, can be of about 150 μm or less, for example. It is submitted that the dimensions of the pad structures 405 and the space between the pad structures 405 can be modified according to the applied technology, i.e., the smaller the applied technology, the smaller the dimensions of the pad structures 405 and the space between the pad structures 405.

Referring again to FIG. 3, the pad structure 305 is coupled to more than one bump structure 300. In some embodiments, one of the bump structures 300 can serve as a redundancy for repair if the other bump structure 300 fails. In still other embodiments, a plurality of bump structures 300 are formed adjacent to the pad structure 305 for enhancing adhesion of the substrate 301 to another substrate as shown in FIG. 5.

The process shown in FIGS. 4A-4F is anyone exemplary method for forming the bump structure of FIG. 2A. Other bump structures shown in FIGS. 2B-2F can also be achieved by cooperating the process of FIGS. 4A-4F with the descriptions set forth in connection with FIGS. 2B-2F. Based on the foregoing descriptions of the embodiments, one of ordinary skill in the art can readily form a desired bump structure.

FIG. 5 is a schematic cross-sectional view showing an exemplary packaged structure comprising the bump structure shown in FIG. 2A. Corresponding items shown in FIGS. 5 and 2A are identified by the same reference numerals.

Referring to FIG. 5, a packaged structure 500 comprises the substrate 201 attached to a substrate 501. The substrate 201 with the bump structures 200 is flipped and attached to the substrate 501, which includes pad structures 505. Each of the bump structures 200 from substrate 201 couples to a corresponding pad structure 505 from the substrate 501. The substrate 501 can be, for example, a printed circuit board (PCB), a silicon substrate, III-V compound substrate, display substrate such as a liquid crystal display (LCD), plasma display, cathode ray tube display or electro luminescence (EL) lamp display, or light emitting diode (LED) substrate (collectively referred to as, substrate 501), for example. In some embodiments, the pad structure 505 can be, for example, similar to the pad structure 205 described above. By using the polymer layer 210, stresses applied to the bump structures 200 can be released, such as when the packaged structure 500 is subjected to a stress test, during transportation, use, etc. In some embodiments, an underfill (not shown) is formed between the substrates 201 and 501. In still other embodiments, an underfill is not used if a desired stress release can be achieved through use of the bump structure 200 set forth above.

Although the present invention has been described in terms of exemplary embodiments, it is not limited thereto. Rather, the appended claims should be construed broadly to include other variants and embodiments of the invention which may be made by those skilled in the field of this art without departing from the scope and range of equivalents of the invention.

What is claimed is:

1. A bump structure for bonding two substrates together, comprising:
a composite structure formed over a first substrate, the composite structure comprising at least one first polymer layer and at least one first metal-containing layer; and
a second metal-containing layer at least partially covering a top surface of the composite structure, and extending from the top surface of the composite structure to a surface of the first substrate, wherein the second metal-containing layer is thinner than the first metal-containing layer.

2. The bump structure of claim 1, wherein the first polymer layer has a trapezoidal, semi-spherical, square or rectangular cross-section.

3. The bump structure of claim 1 further comprising at least one conductive plug formed within the first polymer layer, wherein the plug connects the first metal-containing layer to the first substrate.

4. The bump structure of claim 1, wherein the second metal-containing layer has a thickness of about 5,000 Å or less.

5. The bump structure of claim 1 further comprising a second polymer layer formed adjacent to a sidewall of the second metal-containing layer.

6. The bump structure of claim 1,
wherein the first substrate comprises at least one pad structure,
wherein the composite structure is laterally spaced from a corresponding pad structure, and
wherein the second metal-containing layer extends from the top surface of the composite layer to make electrical connection with the corresponding pad structure.

7. The bump structure of claim 1, wherein at least a portion of a top surface of the second metal-containing layer is coupled to a pad structure of a second substrate.

8. The bump structure of claim 1, wherein the first metal-containing layer is formed over the first polymer layer.

9. A bump structure for bonding two substrates together, comprising:
a first polymer layer formed over a first substrate;
a thin metal-containing layer formed over the first polymer layer, wherein the thin metal-containing layer at least partially covers the first polymer layer and extends from the top surface of the first polymer layer to a surface of the first substrate; and
a conductive layer formed over the thin metal-containing layer, the conductive layer substantially covering a top surface of the thin metal-containing layer.

10. The bump structure of claim 9, wherein the first polymer layer has a trapezoidal, semi-spherical, square or rectangular cross-section.

11. The bump structure of claim 9 further comprising at least one conductive plug formed within the first polymer layer, wherein the conductive plug connects the thin metal-containing layer to the first substrate.

12. The bump structure of claim 9, wherein the thin metal-containing layer has a thickness of about 5,000 Å or less.

13. The bump structure of claim 9 further comprising a second polymer layer formed adjacent to a sidewall of the thin metal-containing layer.

14. The bump structure of claim 9,
wherein the first substrate comprises at least one pad structure,
wherein the first polymer layer is laterally spaced from a corresponding pad structure, and
wherein the thin metal-containing layer extends from the top surface of the first polymer layer to make electric contact with the corresponding pad structure.

15. The structure of claim 9, wherein the conductive layer is a metal-containing layer having a thickness between about 50 μm and about 60 μm.

16. The structure of claim 9 further comprising a second polymer layer formed between the thin metal-containing layer and the conductive layer.

17. The structure of claim 9, wherein at least a portion of a top surface of the conductive layer is attached to a pad structure of a second substrate.

18. A packaged structure, comprising:
a plurality of bump structures, each of the bump structures comprising:
a composite structure over a first substrate, the composite structure comprising at least one first polymer layer and at least one first metal-containing layer; and
a second metal-containing layer at least partially covering a top surface of the composite structure, and extending from the top surface of the composite structure to a surface of the first substrate, wherein the second metal-containing layer is thinner than the first metal-containing layer; and
a plurality of first pad structures formed on a second substrate, wherein at least some of the bump structures are attached to corresponding first pad structures from the second substrate.

19. The packaged structure of claim 18 further comprising at least one conductive plug formed within the first polymer layer, wherein the plug connects the first metal-containing layer to the first substrate.

20. The packaged structure of claim 18, wherein the second metal-containing layer has a thickness of about 5,000 Å or less.

21. The packaged structure of claim 18,
wherein the first substrate comprises at least one second pad structure,
wherein the bump structure is laterally spaced from a corresponding second pad structure, and
wherein the second metal-containing layer extends from the top surface of the composite structure to the corresponding second pad structure.

22. The packaged structure of claim 18, wherein the first metal-containing layer is formed over the first polymer layer.
